(19) United States
(12) Patent Application Publication
(10) Pub. No.: US 2009/0117290 A1
(43) Pub. Date: May 7, 2009

(54) METHOD OF MANUFACTURING NON-SHRINKAGE CERAMIC SUBSTRATE

(75) Inventors: Hyung Ho KIM, Suwon (KR); Jong Myeon Lee, Gwacheon (KR); Eun Tae Park, Yongin (KR); Soo Hyun Lyoo, Yongin (KR)

Correspondence Address: MCDERMOTT WILL & EMERY LLP, 18191 VON KARMAN AVE., SUITE 500, IRVINE, CA, 92612-7108, US

(73) Assignee: SAMSUNG ELECTRO-MECHANICS CO., LTD, Suwon (KR)

(21) Appl. No.: 12/265,692

(22) Filed: Nov. 5, 2008

(30) Foreign Application Priority Data
Nov. 7, 2007 (KR) 10-2007-0113359

(51) Int. Cl. B05D 5/12; C23C 14/30; C23C 14/34

(52) U.S. Cl. 427/597; 427/123; 427/124; 204/192.12

(57) ABSTRACT

In a method of manufacturing a non-shrinkage ceramic substrate, a ceramic laminated structure, which is formed of a plurality of laminated green sheets each having an interconnecting pattern and has an external electrode formed on at least one of a top and bottom thereof, is prepared. A metal layer is formed to cover at least a portion of the external electrode. A constraining green sheet is disposed on at least one of the top and bottom of the ceramic laminated structure to suppress a planar shrinkage of the green sheets. The ceramic laminated structure is fired at the firing temperature of the green sheets to oxidize the metal layer. The constraining green sheet and a metal oxide layer, which is formed by oxidizing the metal layer, are removed. Accordingly, an electrode post-firing process can be omitted and the adhering strength between the electrode and the ceramic laminated structure can be increased.

### CROSS-REFERENCE TO RELATED APPLICATIONS

This application claims the priority of Korean Patent Application No. 2007-0113359 filed on Nov. 7, 2007, in the Korean Intellectual Property Office, the disclosure of which is incorporated herein by reference.

### BACKGROUND OF THE INVENTION

1. Field of the Invention

The present invention relates to a method of manufacturing a non-shrinkage ceramic substrate, and more particularly, to a method of manufacturing a non-shrinkage ceramic substrate, which can omit an electrode post-firing process and can increase the adhering strength between an electrode and a ceramic laminated structure.

2. Description of the Related Art

In general, a multi-layer ceramic substrate is used for a complex of passive devices (e.g., a capacitor, an inductor and resistor) and an active device (e.g., a semiconductor IC chip), or is used for a simple semiconductor IC package. Specifically, the multi-layer ceramic substrate is widely used to construct a variety of electronic components such as a Power Amplifier (PA) module substrate, a Radio Frequency (RF) diode switch, a filter, a chip antenna, various package components, and a composite device.

For manufacture of the multi-layer ceramic substrate, green sheets, which have an interconnecting conductor formed therein, are laminated and a firing process must be performed for the resulting structure in order to achieve the excellent characteristics thereof. The performance of the firing process causes the shrinkage of the ceramic by firing. However, it is difficult for the ceramic shrinkage to be uniform throughout the multi-layer ceramic substrate, which causes the dimensional deformation of a ceramic layer in the planar direction.

Also, the planar shrinkage causes an undesirable deformation or distortion in the interconnecting conductor. Specifically, the planar shrinkage causes a reduction in the positional accuracy of an external electrode for the connection of a chip component mounted on the multi-layer ceramic substrate, or causes a disconnection in the interconnecting conductor.

Also, the planar shrinkage causes a misalignment between the conductor pattern and the mounted component, thus making it impossible to mount semiconductor chips, such as Chip Size Packages (CSPs) and Multi-Chip Modules, with high accuracy. Thus, a so-called non-shrinkage process is recently proposed to eliminate the planar shrinkage during the firing process in manufacturing the multi-layer ceramic substrate.

A generally used non-shrinkage process fabricates constraining green sheets by using alumina power, which is ceramic that is not sinterable below 900° C., laminates the constraining green sheets on the top and bottom of a Low-Temperature Cofired Ceramic (LTCC) green sheet, presses the top and bottom of the laminated green sheets, performing a sintering/firing process for the resulting structure, and removes the constraining green sheets, thereby manufacturing a ceramic substrate.

FIGS. 1A to 1D are cross-sectional views illustrating a method of manufacturing a non-shrinkage ceramic substrate according to the related art.

Referring to FIG. 1A, a plurality of green sheets 10, in which internal electrodes 20 and conductive via holes 30 for connection of electrodes in different layers are formed at suitable locations according to a module circuit diagram, are prepared. Thereafter, the green sheets 10 are laminated to form a ceramic laminated structure 100.

Thereafter, constraining green sheets 40 (e.g., alumina (Al₂O₃) sheets), which are not firable at the firing temperature of the green sheets 10, are laminated on the top and bottom of the ceramic laminated structure 100, and the resulting structure is pressed, sintered and fired.

Referring to FIG. 1B, a lapping process is used to remove the constraining green sheets 40. In this case, during the firing process, materials such as alumina, glass, and binder are diffused to form a diffusion layer at an interface between the ceramic laminated structure 100 and the constraining green sheet 40. Because the diffusion layer is unsuitable for formation of an external electrode, it is necessary to also remove the diffusion layer through the lapping process.

Referring to FIG. 1C, a well-known screen printing process is used to form external electrodes 50 on the top and bottom of the ceramic laminated structure 100 in such a way that the external electrodes 50 are connected to the conductive via holes 30 exposed by the lapping process.

Specifically, the forming of the external electrodes 50 on the top and bottom of the ceramic laminated structure 100 includes: disposing a screen 60 with a given number of meshes on the ceramic laminated structure 100; disposing an Ag Cu or Ni paste 52 for the external electrodes on the top of the screen 60; and pushing the paste 52 to the bottom of the screen 60 by means of a squeezer 70 to print the external electrodes 50 on the top and bottom of the ceramic laminated structure 100.

Referring to FIG. 1D, the resulting structure including the printed external electrodes 50 are post-fired at temperatures of 500° C. to 900° C.

As described above, the non-shrinkage ceramic substrate manufacturing method according to the related art performs two firing processes, that is, the firing process for the ceramic laminated structure and the post-firing process for the external electrodes. However, because the external electrode is fired separately after the firing of the ceramic laminated structure, the adhering strength between the ceramic laminated structure and the external electrode fired by the post-firing process is not high, thus degrading the electrical characteristics of the ceramic substrate.

Also, the non-shrinkage ceramic substrate manufacturing method according to the related art requires the lapping process and the post-firing process as described above, thus causing a process inefficiency and a manufacturing cost increase.

### SUMMARY OF THE INVENTION

An aspect of the present invention provides a method of manufacturing a non-shrinkage ceramic substrate, which can omit an electrode post-firing process and can increase the adhering strength between an electrode and a ceramic laminated structure.

According to an aspect of the present invention, there is provided a method of manufacturing a non-shrinkage ceramic substrate, the method including: preparing a ceramic laminated structure that is formed of a plurality of laminated green sheets each having an interconnecting pattern and has an external electrode formed on at least one of a top and bottom thereof; forming a metal layer to cover at least a portion of the external electrode; disposing a constraining green sheet on at least one of the top and bottom of the ceramic laminated structure to suppress a planar shrinkage of the green sheets; firing the ceramic laminated structure at the firing temperature of the green sheets to oxidize the metal layer; and removing the constraining green sheet and a metal oxide layer formed by oxidizing the metal layer.

According to an embodiment of the present invention, the metal layer is formed of aluminum (Al).

Herein, the metal layer may be formed to cover all of the top of the external electrode. Furthermore, the metal layer may cover all of the exposed surface of the external electrode.

In consideration of a glass diffusion preventing function and the convenience in the process, it is preferable that the metal layer has a thickness of about 0.1 μm to about 10 μm.

In this case, the metal layer may have a thickness of about 0.5 μm to about 5 μm.

Herein, the metal layer may be formed through one selected from the group consisting of a sputtering process, an electron beam process, a physical vapor deposition process, a sol-gel process, and a screen printing process.

According to an embodiment of the present invention, the ceramic laminated structure may be fired at a temperature of about 800° C. to about 900° C.

Herein, the external electrode may include at least one selected from the group consisting of Ag, Cu and Ni.

Also, the constraining green sheet may be disposed on each of the top and bottom of the ceramic laminated structure.

The method may further include: forming a plating layer on the external electrode after the removing of the constraining green sheet and the metal oxide layer.

In this case, the plating layer may be formed by electrodeless-plating Ni and Au sequentially.

### BRIEF DESCRIPTION OF THE DRAWINGS

The above and other aspects, features and other advantages of the present invention will be more clearly understood from the following detailed description taken in conjunction with the accompanying drawings, in which:

FIGS. 1A to 1D are cross-sectional views illustrating a method of manufacturing a non-shrinkage ceramic substrate according to the related art; and

FIGS. 2A to 2F are cross-sectional views illustrating a method of manufacturing a non-shrinkage ceramic substrate according to an embodiment of the present invention.

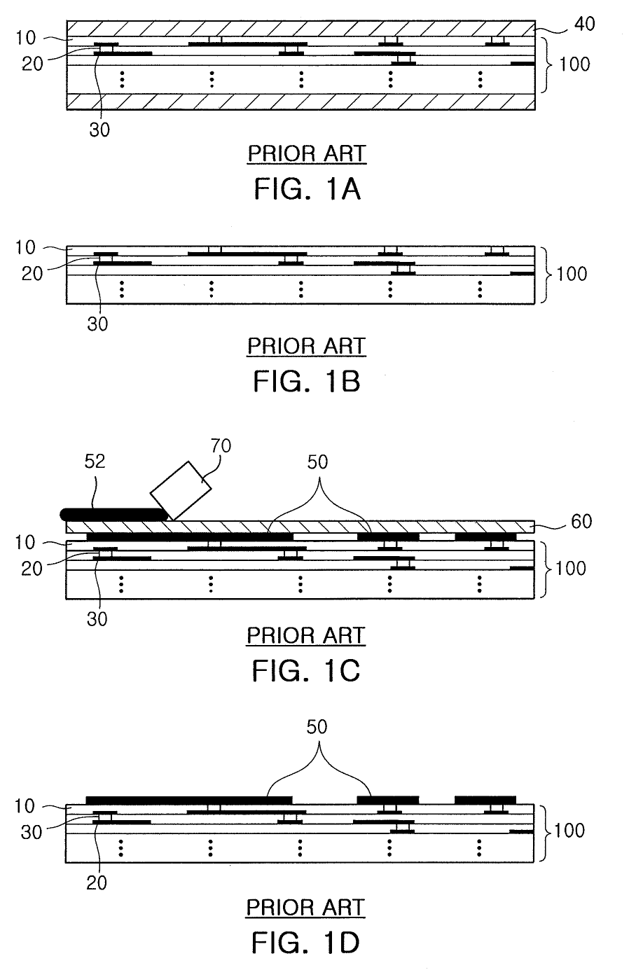

### DETAILED DESCRIPTION OF THE PREFERRED EMBODIMENT

Exemplary embodiments of the present invention will now be described in detail with reference to the accompanying drawings. The invention may, however, be embodied in many different forms and should not be construed as being limited to the embodiments set forth herein; rather, these embodiments are provided so that this disclosure will be thorough and complete, and will fully convey the concept of the invention to those skilled in the art. In the drawings, the thicknesses of layers and regions are exaggerated for clarity. Like reference numerals in the drawings denote like elements, and thus their description will be omitted.

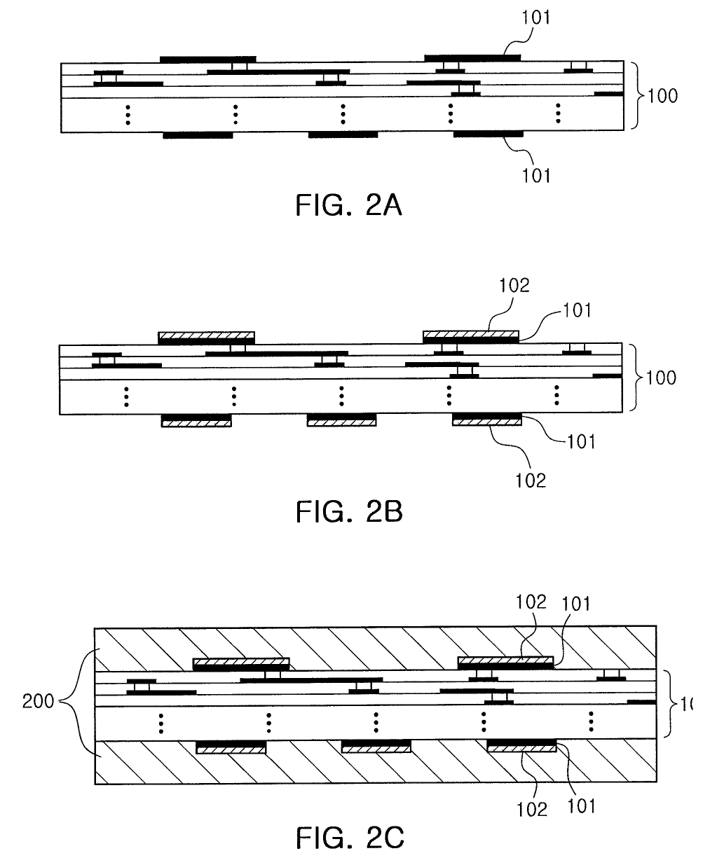

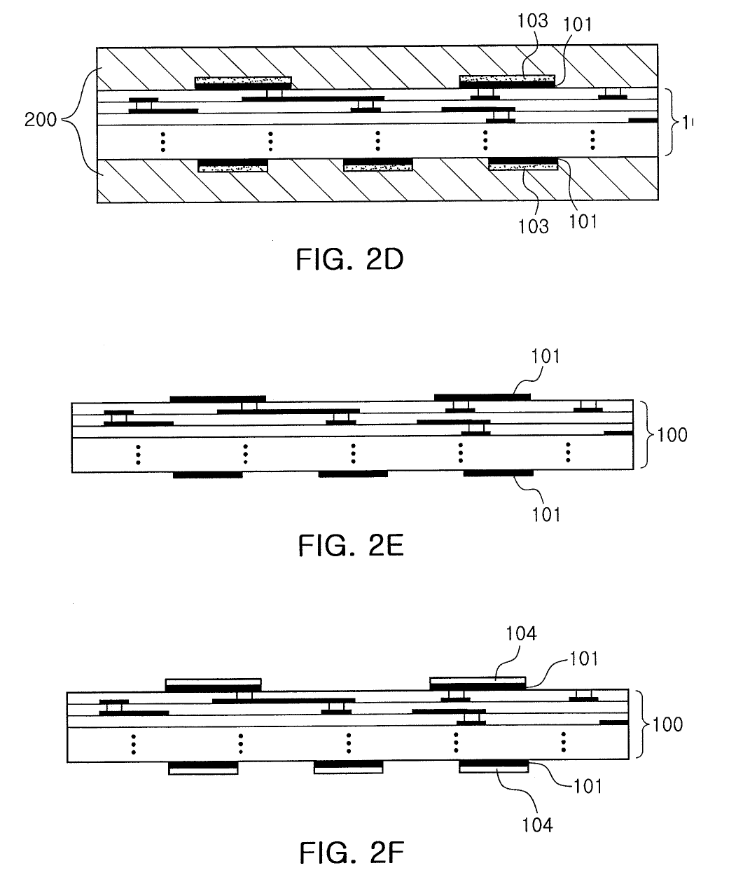

FIGS. 2A to 2F are cross-sectional views illustrating a method of manufacturing a non-shrinkage ceramic substrate according to an embodiment of the present invention.

Referring to FIG. 2A, a plurality of green sheets are laminated to prepare a ceramic laminated structure 100.

Each of the green sheets of the ceramic laminated structure 100 includes glass, binder and ceramic filler, and may be prepared through a well-known process such as a doctor blade process. An internal electrode is formed in the green sheet, and the green sheet has a conductive via hole formed for an electrical connection between the respective layers. In particular, an external electrode 101 is formed on the outermost green sheet of the ceramic laminated structure 100 in such a way that the external electrode 101 is electrically connected to the internal electrode and the conductive via hole.

The internal electrode and the external electrode 101 may be formed of Ag, Cu or Ni through a screen printing process. The conductive via hole may be formed by irradiating laser beams onto the green sheet to form holes and filling the holes with a conductive material or plating the inner wall thereof. The external electrode 101 may be formed on both of the top and bottom surfaces of the ceramic laminated structure 100, or may be formed on only one of the top and bottom surfaces of the ceramic laminated structure 100.

Referring to FIG. 2B, a metal layer 102 is formed to cover the external electrode 101.

As will be described layer, the metal layer 102 is oxidized by a firing process, so that the metal layer 102 changes into a metal oxide layer with a very fine crystal structure. Accordingly, it is possible to effectively prevent the separation of glass from the green sheet and the generation of a diffusion layer, which are the problems of the related art. In consideration of this function, it is most preferable that the metal layer 102 is formed of aluminum (Al). Also, in consideration of the glass diffusion preventing function and the convenience in the process, it is preferable that the metal layer 102 is formed to a thickness of about 0.1 μm to about 10 μm, and it is more preferable that the metal layer 102 is formed to a thickness of about 0.5 μm to about 5 μm.

The metal layer 102 may be formed through a sputtering process, an electron beam process, a physical vapor deposition process, a sol-gel process, or a screen printing process.

Although the present embodiment illustrates that the metal layer 102 is formed on the top of the external electrode 101 in accordance with the dimension and shape of the external electrode 101, the present invention is not limited thereto. For example, the formation range of the metal layer 102 may be controlled in consideration of the diffusion layer preventing function and the convenience in the removal after the firing process. For example, the metal layer 102 may be formed to cover all the external electrode 101 in order to more effectively prevent the diffusion between the green sheet and a constraining green sheet.

Referring to FIG. 2C, a constraining green sheet 200 such as an alumina (Al₂O₃) sheet is deposited to a thickness of about 50 μm to about 500 μm to cover the top and bottom of the ceramic laminated structure 100.

The constraining green sheet 200 is provided to suppress the planar shrinkage of the ceramic laminated structure 100. The constraining green sheet 200 is formed of material such as alumina (Al₂O₃) that is not firable at the firing temperature of the ceramic laminated structure 100.

Thereafter, the ceramic laminated structure 100 having the constraining green sheet 200 deposited thereon is pressed, sintered and fired. Herein, it is preferable that the firing process is performed at about 800° C. to about 900° C. that is the general firing temperature of the green sheet. The constraining green sheet 200 serves to prevent the planar shrinkage of the green sheets of the ceramic laminated structure 100 during the firing process.

Referring to FIG. 2D, the metal layer 102 is oxidized by the firing process so that the metal layer 102 changes into a metal oxide layer 103. For example, if the metal layer 102 is formed of aluminum, the aluminum layer reacts with oxygen at about 850° C. so that the aluminum layer changes into an aluminum oxide (Al₂O₃) layer.

In this case, the aluminum oxide (Al₂O₃) layer is identical in compositional formula to the aluminum of the constraining green sheet, but is greatly different in crystal structure from the aluminum of the constraining green sheet. For example, the aluminum oxide (Al₂O₃) layer may be a oxide layer with a very fine crystal structure.

In this way, in the present embodiment, because the oxidation process occurs simultaneously during the firing process for the ceramic laminated structure 100, the metal layer 102 can smoothly change into the metal oxide layer 103. Accordingly, the metal oxide layer 103 can minimize the movement of the glass of the green sheet by diffusion through the external electrode 101 to the constraining green sheet 200.

That is, the use of the ceramic substrate manufacturing method according to the present embodiment can solve the problem of a degradation in the adhering strength and the plating property of the external electrode surface by the diffusion of the alumina, the glass and the binder, and can also facilitate the plating process because non-fired alumina powder does not remain on the surface of the external electrode 101.

Thus, unlike the related art, the post-printing process and the post-firing process are unnecessary, and the reliability can be conveniently achieved because of the sufficient adhering force between the ceramic material and the collided metal.

Referring to FIG. 2E, the constraining green sheet 200 and the metal oxide layer 103 are removed from the resulting structure.

Specifically, the constraining green sheet 200 may be generally removed by using a well-known lapping process. Also, the metal oxide layer 103 may be easily removed by applying a small thermal shock thereto because the metal oxide layer 103 is a kind of ceramic and thus is different in thermal expansion coefficient from the external electrode 101 formed of metal.

Referring to FIG. 2F, a plating layer 104 is formed on the external electrode 101. In this case, the plating layer 104 may be formed by electrodeless-plating Ni and Au sequentially. The process illustrated in FIG. 2F is not essential in the present invention and thus it may be omitted according to circumstances.

As described above, the method of manufacturing the non-shrinkage ceramic substrate according to the present invention can omit the electrode post-firing process and can increase the adhering strength between the electrode and the ceramic laminated structure.

While the present invention has been shown and described in connection with the exemplary embodiments, it will be apparent to those skilled in the art that modifications and variations can be made without departing from the spirit and scope of the invention as defined by the appended claims.

What is claimed is:

1. A method of manufacturing a non-shrinkage ceramic substrate, the method comprising:
preparing a ceramic laminated structure that is formed of a plurality of laminated green sheets each having an interconnecting pattern and has an external electrode formed on at least one of a top and bottom thereof;
forming a metal layer to cover at least a portion of the external electrode;
disposing a constraining green sheet on at least one of the top and bottom of the ceramic laminated structure to suppress a planar shrinkage of the green sheets;
firing the ceramic laminated structure at the firing temperature of the green sheets to oxidize the metal layer; and
removing the constraining green sheet and a metal oxide layer formed by oxidizing the metal layer.

2. The method of claim 1, wherein the metal layer is formed of aluminum (Al).

3. The method of claim 1, wherein the metal layer is formed to cover all of the top of the external electrode.

4. The method of claim 3, wherein the metal layer covers all of the exposed surface of the external electrode.

5. The method of claim 1, wherein the metal layer has a thickness of about 0.1 μm to about 10 μm.

6. The method of claim 5, wherein the metal layer has a thickness of about 0.5 μm to about 5 μm.

7. The method of claim 1, wherein the metal layer is formed through one selected from the group consisting of a sputtering process, an electron beam process, a physical vapor deposition process, a sol-gel process, and a screen printing process.

8. The method of claim 1, wherein the ceramic laminated structure is fired at a temperature of about 800° C. to about 900° C.

9. The method of claim 1, wherein the external electrode comprises at least one selected from the group consisting of Ag, Cu and Ni.

10. The method of claim 1, wherein the constraining green sheet is disposed on each of the top and bottom of the ceramic laminated structure.

11. The method of claim 1, further comprising:
forming a plating layer on the external electrode after the removing of the constraining green sheet and the metal oxide layer.

12. The method of claim 11, wherein the plating layer is formed by electrodeless-plating Ni and Au sequentially.
